(19) United States
(12) Patent Application Publication
(10) Pub. No.: US 2026/0333680 A1
(43) Pub. Date: Oct. 22, 2026

(54) HIGH-DENSITY OTP MEMORY

(71) Applicant: Sichuan Kiloway Technologies Co., Ltd., Mianyang City (CN)

(72) Inventors: Junhua MAO, Mianyang City (CN); Jack Zezhong PENG, Mianyang City (CN); Ming LEI, Mianyang City (CN); Chuandong TAO, Mianyang City (CN); Kun WANG, Mianyang City (CN)

(21) Appl. No.: 19/468,661

(22) Filed: Feb. 3, 2026

(30) Foreign Application Priority Data
Feb. 6, 2025 (CN) 202510131837.8
Feb. 7, 2025 (CN) 202510135161.X

(51) Int. Cl. H10B 20/25; G11C 17/16; G11C 17/18; H10B 20/00

(52) U.S. Cl. CPC H10B 20/25; G11C 17/16; G11C 17/18; H10B 20/60

(57) ABSTRACT

A high-density One-Time Programmable (OTP) memory including an array formed by arranging a predetermined number of memory cells is provided. A memory cell includes: an anti-fuse storage Metal Oxide Semiconductor (MOS) transistor, a voltage division MOS transistor, and a selection MOS transistor. The voltage division MOS transistor includes a source region with a second conductivity type, a drain region with a second conductivity type and a substrate with a first conductivity type, where the source region of the voltage division MOS transistor includes a second conductivity type region and a second-conductivity-type lightly doped region, the drain region only has a second conductivity type region, doping concentrations of the second conductivity type regions in the source region and the drain region are the same, and a doping concentration of the second-conductivity-type lightly doped region is lower than that of the second conductivity type region.

### CROSS-REFERENCE TO RELATED APPLICATIONS

This patent application claims the benefit and priority both of Chinese Patent Application No. 202510135161.X filed with the China National Intellectual Property Administration on Feb. 7, 2025, and Chinese Patent Application No. 202510131837.8 filed with the China National Intellectual Property Administration on Feb. 6, 2025, the disclosures of which are incorporated by reference herein in their entirety as part of the present application.

### TECHNICAL FIELD

The present disclosure relates to an integrated circuit technology, and in particular, to a memory technology.

### BACKGROUND

Patent documents CN113707207A and U.S. Ser. No. 10/510,427B2 disclose anti-fuse memory technologies based on Metal Oxide Semiconductor (MOS) transistors. FIG. 1 shows a MOS transistor structure in a Prior art. Gate-Induced Drain Leakage (GIDL) breakdown voltage of a traditional Metal-Oxide-Semiconductor Field Effect Transistor (MOSFET) is relatively low. GIDL is gate-induced drain leakage current, which occurs below a gate-drain overlap region. In a traditional Complementary Metal Oxide Semiconductor (CMOS), a Lightly Doped Drain (LDD) provides a short connection path under a side wall between an inversion channel below a Gate and a drain. Because an LDD region and the Gate are extremely close to each other, and even overlap with each other from a projection perspective. Under relatively high Gate-Drain (G-D) reverse voltage, the Gate has to be aligned with a source-drain in device structure, but it is impossible to absolutely align the Gate with the source-drain, so an overlap is inevitable. For an overlap region of a Drain and the Gate (using a N-Channel Metal Oxide Semiconductor (NMOS) as an example), when a negative bias voltage is applied to the gate or strong positive bias voltage is applied to the drain, holes of majority carriers, serving as a substrate, accumulate near a drain LDD on a surface and deplete/deeply deplete original N-type silicon, tending to invert the region. As a result, a depletion region of the drain LDD extends to the drain, achieving an effect like p+ doping, and occurring strong band bending due to an induced electric field. In this case, when the band bending becomes greater than a band gap, that is, when a valence band Ev becomes higher than a conduction band Ec, electrons flow into the drain through a tunneling effect and generate leakage current. Due to Electron-Hole Pairs (EHPs) generated by heat, holes flow into the substrate and electrons flow into the drain, thereby increasing the leakage current. In addition, if a device deteriorates due to Negative Bias temperature Instability (NBTI), Positive Bias temperature Instability (PBTI), or Hot Carrier Injection (HCI) stress, traps in an interface will generate trap-assisted tunneling current to further increase GIDL current, and the GIDL leakage current is formed by various factors.

US Patent Document US20090090980A1 discloses an asymmetric LDD-type MOS transistor that is compatible with a standard CMOS technology and does not require an additional mask. To create a region with large voltage drop on a drain side, the drain LDD is removed by blocking LLD/Halo injection. Forming LDD/Halo injection through a mask tool only requires one logic operation layer, so additional process steps are not required. Significant improvement of a drain breakdown voltage (BVdss) is the design of a wide depletion region below a sidewall region and between the drain and substrate, which reduces a peak electric field on a drain side and can support higher reverse bias drain voltage than that in traditional cases.

### SUMMARY

A technical problem to be solved by the present disclosure is to provide a high-density One-Time Programmable (OTP) memory with a simple structure and a small size.

A technical solution adopted by the present disclosure to solve the technical problem is that a high-density OTP memory includes an array formed by arranging a predetermined number of memory cells. A memory cell includes:
an anti-fuse storage MOS transistor, where a gate of the anti-fuse storage MOS transistor is connected to a first word line WP;
a voltage division MOS transistor, where a gate of the voltage division MOS transistor is connected to a second word line WB, and a first current end of the voltage division MOS transistor is connected to a current end of the anti-fuse storage MOS transistor; and
a selection MOS transistor, where a gate of the selection MOS transistor is connected to a third word line WS, a first current end of the selection MOS transistor is connected to a second current end of the voltage division MOS transistor, and a second current end of the selection MOS transistor is connected to a first bit line BL.

The voltage division MOS transistor includes a source region with a second conductivity type, a drain region with a second conductivity type and a substrate with a first conductivity type, where the source region of the voltage division MOS transistor includes a second conductivity type region and a second-conductivity-type lightly doped region, the drain region only has a second conductivity type region, a doping concentration of the second conductivity type region in the source region is same as that of the second conductivity type region in the drain region, and a doping concentration of the second-conductivity-type lightly doped region is lower than that of the second conductivity type region.

Further, the memory cell further includes a detection MOS transistor, where a connection point between the selection MOS transistor and the voltage division MOS transistor is connected to a gate of the detection MOS transistor, a first current end of the detection MOS transistor is connected to the first bit line BL, and a second current end of the detection MOS transistor is connected to a second bit BR.

Further, the second current end of the detection MOS transistor is connected to the second bit line BR through an isolation MOS transistor, and a gate of the isolation MOS transistor is connected to a fourth word line.

The voltage division MOS transistor is a native MOS transistor.

The present disclosure has the following beneficial effects. The success rate of writing can be greatly improved by adopting the technology of the present disclosure. Comparative tests are performed on sample wafers obtained by adopting a conventional method and by adopting the present disclosure, each wafer includes about 360,000 grains. The success rate of writing is as follows:

| Power voltage | Using conventional art | Using the present disclosure |
|---|---|---|
| 2.0 V | <10% | 97% |
| 2.5 V | 95% | >99% |

### BRIEF DESCRIPTION OF THE DRAWINGS

FIG. 1 is a schematic structural diagram of a MOS transistor.

FIG. 2 is a schematic structural diagram of an asymmetric MOS transistor used by the present disclosure.

FIG. 3 is a circuit diagram of Embodiment 1 of the present disclosure.

FIG. 4 is a circuit diagram of Embodiment 2 of the present disclosure.

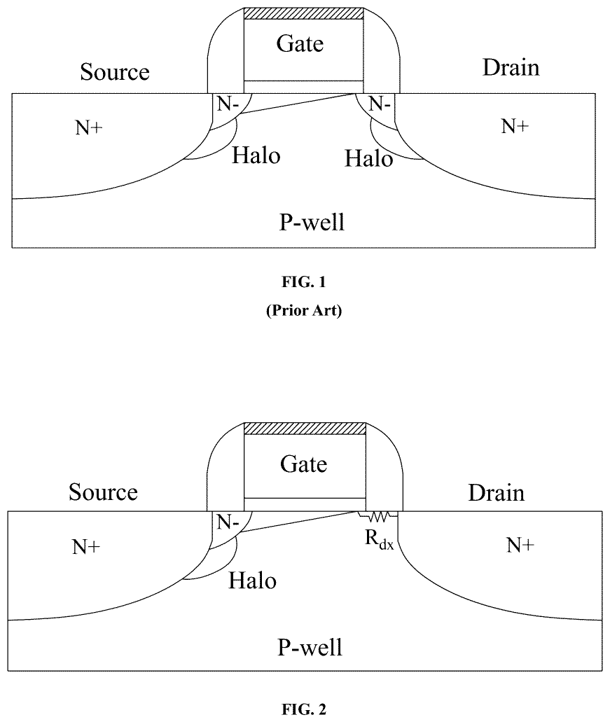

### DETAILED DESCRIPTION OF THE EMBODIMENTS

A high-density OTP memory includes an array formed by arranging a predetermined number of memory cells. A memory cell includes:
an anti-fuse storage MOS transistor, where a gate of the anti-fuse storage MOS transistor is connected to a first word line WP;
a voltage division MOS transistor, where a gate of the voltage division MOS transistor is connected to a second word line WB, and a first current end of the voltage division MOS transistor is connected to a current end of the anti-fuse storage MOS transistor; and
a selection MOS transistor, where a gate of the selection MOS transistor is connected to a third word line WS, a first current end of the selection MOS transistor is connected to a second current end of the voltage division MOS transistor, and a second current end of the selection MOS transistor is connected to a first bit line BL. The number of the anti-fuse storage MOS transistor may be one, the number of the voltage division MOS transistor may be one, and the number of the selection MOS transistor may be one.

The voltage division MOS transistor includes a source region with a second conductivity type, a drain region with a second conductivity type and a substrate with a first conductivity type, where the source region of the voltage division MOS transistor includes a second conductivity type region and a second-conductivity-type lightly doped region, the drain region only has a second conductivity type region, doping concentrations of the second conductivity type regions of the source region and the drain region are the same, and a doping concentration of the second-conductivity-type lightly doped region is lower than that of the second conductivity type region.

The memory cell further includes a detection MOS transistor, where a connection point between the selection MOS transistor and the voltage division MOS transistor is connected to a gate of the detection MOS transistor, a first current end of the detection MOS transistor is connected to the first bit line BL, and a second current end of the detection MOS transistor is connected to a second bit BR. The number of the detection MOS transistor may be one.

The second current end of the detection MOS transistor is connected to the second bit line BR through an isolation MOS transistor, and a gate of the isolation MOS transistor is connected to a fourth word line.

Preferably, the voltage division MOS transistor is a native MOS transistor.

For example, the gate of the anti-fuse storage MOS transistor is connected to the first word line WP, the gate of the voltage division MOS transistor is connected to the second word line WB, and the gate of the selection MOS transistor is connected to the third word line WS. The first current end (drain end) of the selection MOS transistor is connected to the source end of the voltage division MOS transistor, and the second current end (source end) of the selection MOS transistor is connected to the first bit line BL. The voltage division MOS transistor includes the source region with the second conductivity type (N-type doping), the drain region with the second conductivity type (N-type doping) and the substrate with the first conductivity type (P-type doing). The source region of the voltage division MOS transistor includes the second conductivity type region (N+ region) and the second-conductivity-type lightly doped region (N− region). The drain region only has the second conductivity type region (N+ region). The doping concentrations of the second conductivity type regions (N+ regions) of the source region and the drain region are the same, and the doping concentration of the second-conductivity-type lightly doped region (N− region) is lower than that of the second conductivity type region (N+ region).

### Embodiment 1

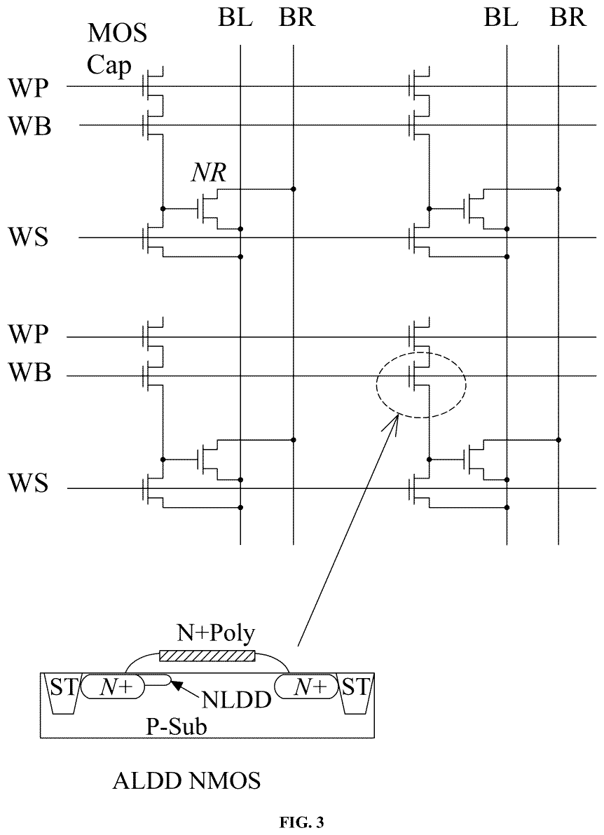

Referring FIG. 3, a circuit shown in FIG. 3 is an improved circuit based on a circuit in US Patent Document U.S. Ser. No. 10/510,427B2. A voltage division MOS transistor (shown in a dashed part) is improved in this embodiment, and a MOS transistor with an asymmetric LDD (ALDD) structure is used as the division MOS transistor. A source region of the voltage division MOS transistor includes a second conductivity type region (N+ region) and a second-conductivity-type lightly doped region (N− region, that is NLDD). The drain region only has a second conductivity type region (N+ region), and the drain region is not provided with the second-conductivity-type lightly doped region (N− region).

### Embodiment 2

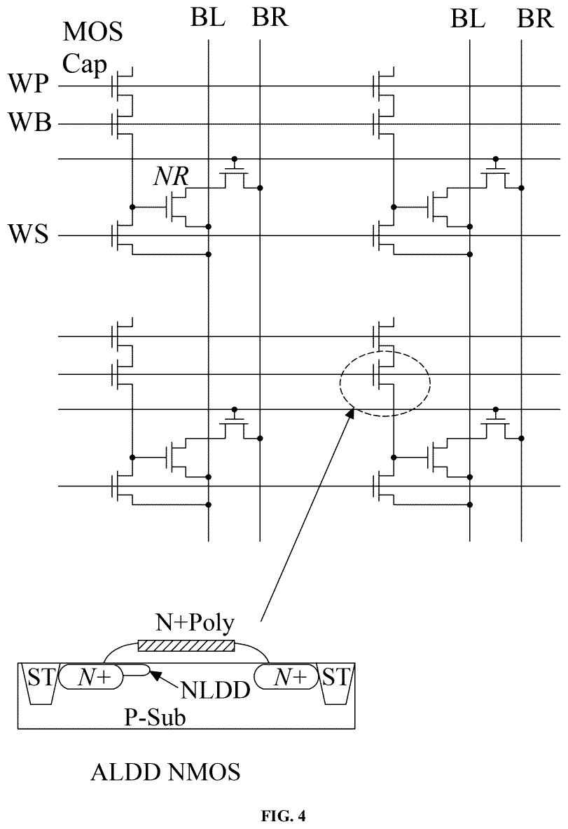

Referring FIG. 4, a memory cell shown in FIG. 4 is an improved memory cell based on a memory cell in Chinese Patent Document CN113707207A. A voltage division MOS transistor (shown in a dashed part) is improved in this embodiment, and a MOS transistor with an asymmetric LDD structure is used as the division MOS transistor. A source region of the division MOS transistor includes a second conductivity type region (N+ region) and a second-conductivity-type lightly doped region (N− region). The drain region only has a second conductivity type region (N+ region), and the drain region is not provided with the second-conductivity-type lightly doped region (N− region).

As further improvement of Embodiment 1 and Embodiment 2, the anti-fuse storage MOS transistor may adopt a native MOS transistor because the native MOS transistor has lower threshold voltage than that of a conventional MOS transistor. A dielectric between a gate of the programmed storage transistor and a channel forms high resistance conduction between the gate and the channel due to breakdown, conduction between the channel and a source depends on formation of the channel, and detection current can form a path through the gate-channel-source only in the existence of both the conduction between the gate and the channel and the conduction between the channel and the source. A channel can be formed and conducted only when voltage applied between the gate and the source of the MOS transistor is higher than threshold voltage, and voltage obtained at the source has a voltage drop loss of a threshold compared with gate voltage. The current from the storage transistor can reach a detection circuit further through a voltage division transistor. Similarly, drain-source conduction of the voltage division transistor also depends on formation of the channel, and the voltage obtained at the source of the voltage division transistor also has a voltage drop loss of a threshold compared with gate voltage. Therefore, by adopting the native MOS transistor, the storage transistor and the voltage division transistor can reduce a voltage drop loss caused by threshold voltage when detection current flows through, thereby obtaining higher detection voltage at the gate of the detection transistor NR, and reducing excitation voltage required for detection.

What is claimed is:

1. A One-Time Programmable (OTP) memory, comprising an array formed by arranging a predetermined number of memory cells, wherein each memory cell comprises:
an anti-fuse storage Metal Oxide Semiconductor (MOS) transistor, wherein a gate of the anti-fuse storage MOS transistor is connected to a first word line WP;
a voltage division MOS transistor, wherein a gate of the voltage division MOS transistor is connected to a second word line WB, and a first current end of the voltage division MOS transistor is connected to a current end of the anti-fuse storage MOS transistor; and
a selection MOS transistor, wherein a gate of the selection MOS transistor is connected to a third word line WS, a first current end of the selection MOS transistor is connected to a second current end of the voltage division MOS transistor, and a second current end of the selection MOS transistor is connected to a first bit line BL; wherein
the voltage division MOS transistor comprises a source region with a second conductivity type, a drain region with the second conductivity type and a substrate with a first conductivity type, wherein the source region of the voltage division MOS transistor comprises a second conductivity type region and a second-conductivity-type lightly doped region, the drain region only has a second conductivity type region, a doping concentration of the second conductivity type region in the source region is same as that of the second conductivity type region in the drain region, and a doping concentration of the second-conductivity-type lightly doped region is lower than that of the second conductivity type region.

2. The OTP memory according to claim 1, wherein each memory cell further comprises a detection MOS transistor, and wherein a connection point between the selection MOS transistor and the voltage division MOS transistor is connected to a gate of the detection MOS transistor, a first current end of the detection MOS transistor is connected to the first bit line BL, and a second current end of the detection MOS transistor is connected to a second bit BR.

3. The OTP memory according to claim 2, wherein the second current end of the detection MOS transistor is connected to the second bit line BR through an isolation MOS transistor, and a gate of the isolation MOS transistor is connected to a fourth word line.

4. The OTP memory according to claim 1, wherein the voltage division MOS transistor is a native MOS transistor.

5. The OTP memory according to claim 2, wherein the voltage division MOS transistor is a native MOS transistor.

6. The OTP memory according to claim 3, wherein the voltage division MOS transistor is a native MOS transistor.
